(19) United States
(12) Patent Application Publication
(10) Pub. No.: US 2012/0307487 A1
(43) Pub. Date: Dec. 6, 2012

(54) Vehicle LED Reading Light Grouping System and Method

(75) Inventor: David P. Eckel, Fort Salonga, NY (US)

(73) Assignee: B/E AEROSPACE, INC., Wellington, FL (US)

(21) Appl. No.: 13/486,789

(22) Filed: Jun. 1, 2012

Related U.S. Application Data
(60) Provisional application No. 61/492,125, filed on Jun. 1, 2011.

(51) Int. Cl. F21V 9/00; G01R 31/28

(52) U.S. Cl. 362/231; 29/593

(57) ABSTRACT

A method is provided for preparing a plurality of groupings of light-emitting diode (LED) lights, where each grouping comprises a plurality of LEDs that fall within a specified color range from respective target x, y color points, comprising: receiving a source group of LEDs from a supplier, the source group having a specified color range; measuring a color value for each LED in the source group with a color sensor; storing the measured color value along with a unique LED identifier; creating a first grouping of LEDs within the specified color range from a first target x, y color point by identifying a plurality of LEDs from the stored color values that fall within the specified color range and doing the same for a second grouping of LEDs. Lighting assemblies are constructed based on the group associations.

### CROSS REFERENCE TO RELATED APPLICATIONS

The present application claims the benefit of U.S. Provisional Application No. 61/492,125, filed Jun. 1, 2011, entitled, “Vehicle LED Reading Light Grouping System and Method”, herein incorporated by reference.

### BACKGROUND

The invention relates to light-emitting diode—(LED) based reading work lights (RWLs) used in vehicles in passenger service unit (PSU) panels and other areas, and to reducing variability between lights installed in a vehicle.

From an aesthetic standpoint, it is important that illumination sources do not vary in color by a noticeable amount in order to maintain the integrity of an illumination scheme. Unfortunately, the manufacture of LEDs is not generally a precise process, and a particular manufacturing run can produce significant amounts of color variance between the LEDs produced in a single process—and the variation between runs can be even larger.

Currently, optical feedback or calibration is required to ensure color consistency due to lack of consistent and tight LED binning offered by LED manufacturers. Binning refers to a manufacturer's grouping of LEDs according to chromaticity. A tight bin is one in which the chromaticity is only permitted to vary by a small amount for LEDs within a particular bin. However, a tight specification for LED color variance may not be achievable with LED binning alone. Furthermore, tight binning costs more money and may not be guaranteed.

### Table of Acronyms

The following acronyms are used herein:
ANSI American National Standards Institute
CCT correlated color temperature
CFL compact fluorescent lamps
CHC center high ceiling
CIE Commission Internationale de l'Eclairage (French: International Commission on Illumination—standardization body)
CRI color rendering index
CTR central
FLR fluorescent lamps
LAT lateral
LED light-emitting diode
ME MacAdam ellipse
PSC passenger service channel
PSU passenger service unit (panel)
RL reading light
RMA return material authorization
RWL reading work light
SDCM standard deviation of color matching
SSL solid state lighting
TP test panel

### Industry Standards and Guidelines

Color deviation is typically measured in units called a “MacAdam (MA) ellipse”, which can be correlated to a standard deviation of color matching. A MacAdam ellipse refers to the region on a chromaticity diagram containing all colors that are indistinguishable, to the average human eye, from the color at the center of the ellipse. The contour of the ellipse therefore represents the just-noticeable differences of chromaticity between the center point and a point on the edge of the ellipse.

If a single MacAdam ellipse is drawn around a target x, y color coordinate (the x, y value represents a particular color/wavelength) on the CIE 1931 chromaticity chart, each end point of the ellipse will be one standard deviation from the target and thus two standard deviations from each other (note: the CIE 1976 chromaticity chart may also be used with u′, v′ coordinates). Therefore, a three standard deviation of color matching to a certain x, y chromaticity coordinate will yield a 1.5-step MacAdam ellipse. Comparatively speaking, the current ANSI C78.377-2008 for solid state lighting defines chromaticity tolerances in quadrangles that can be correlated to the seven-step MacAdam ellipses used in the compact fluorescent lamps (CFL) specifications as seen in FIG. 1.

Industry standard and alliance groups have recognized the visible concerns with color matching utilizing the current specifications. Thus, industry has seen the ANSI Specification C78.376 for FLR (fluorescent lamps) utilize a 4-step MacAdam ellipse. As solid state lighting, primarily LED technology, continues to progress in material advances, manufacturing process and testing control, the ANSI standard will likely be updated to reflect the ability to utilize tighter tolerance specifications. Current LED manufacturers have recently announced soon-to-market products and binning strategies in the three-step MacAdam ellipse tolerance range. This migration is aligned with recent solid state lighting studies, which provide recommendation for color tolerance criteria in the two-to-four step MacAdam ellipse range depending on application. See, for example, the following references, which are herein incorporated by reference:
Lighting Research Center, Final Report: Developing Color Tolerance Criteria for White LEDs, dated Jan. 26, 2004, Page 2, Summary (recommends that 2-step MacAdam Ellipse binning of white LEDs for applications where the white LEDs are placed side-by-side and are directly visible and four-step MacAdam ellipse for applications where the white LEDs (or white LED fixtures) are not directly visible);
SAE Aerospace Recommended Practice ARP5873 LED Passenger Reading Light Assembly, Issued 2007-03, Page 7, Paragraph 3.1.3 (White Light Color Definition allows for approximately a seven-step MacAdam ellipse, but states that the majority of the population will discern a color difference);

MacAdam ellipses plotted on the CIE 1931 Chromaticity Diagram with centered x, y coordinates are shown in FIG. 2. The ellipses are ten times their actual size, as depicted in MacAdam's paper. Also reference IESNA Lighting Handbook, Ninth Edison, Copyright© 2000, Chapter 3 Vision and Perception, subheading “Suprathreshold Visual Performance”, page 3-22.

MacAdam ellipses are based on side-by-side (adjacent) comparison of light sources, whereby both light sources and/or the resultant light output pattern can be seen at the same time by the same person. Reference IESNA Lighting Handbook, Ninth Edison, Copyright© 2000, Chapter 3 Vision and Perception, subheading “Color Discrimination”, page 3-21.

The color of illumination can often be described by two independent properties: chromaticity (correlated color temperature (CCT)), and color rendering index (CRI). At a high level, CCT refers to the color appearance of a light source, “warm” for low CCT values and “cool” for high CCT values. Color rendering refers to the ability of a light source, with a particular CCT, to render the colors of objects the same as a reference light source of the same CCT. This aspect is typically measured in terms of the CIE General Color Rendering Index. The following Table 1 provides a summary of commonly accepted values/ranges for CCTs.

TABLE 1
LED Industry CCT Values
LED Industry CCT and CRI Values

| | Warm | Neutral | Cool |
|---|---|---|---|
| CCT | 2700-3300 K | 3300 K-5000 K | 5000 K+ |

The CCT is the absolute temperature of a blackbody in degrees Kelvin whose chromaticity most nearly resembles that of a light source. Reference IESNA Lighting Handbook, Ninth Edison, Copyright© 2000, Glossary of Lighting Terminology, page G-8. The CCT relates to the color of light produced by a light source as measured in degrees Kelvin. For instance, when a reference piece of tungsten metal is heated, the color of the metal will gradually shift from red to orange to yellow to white to bluish white. The color of light is measured along this scale, with the more orange/amber color light being referred to as “warm white” and the whiter/blue color light being referred to as “cool white” as shown in FIG. 3.

In physics and color science, the Planckian or black body locus is the path that the color of an incandescent black body would take in a particular chromaticity space as the blackbody temperature changes. It extends from deep red at low temperatures through orange, yellowish white, white, and finally bluish white at very high temperatures. FIG. 4 from the Lighting Research Center shows the CIE 1976 Chromaticity Diagram with six isothermal CCT lines typically used by manufactures to represent light emitted by commercially available “white” light fluorescent lamps.

ANSI_NEMA_ANSLG C78.377-2008 provides a Specification for the Chromaticity of Solid State Lighting (SSL) Products. For lighting products that provide white light, the color temperature range is typically specified from nominal CCT categories 2,700 K to 6,500 K as shown in Table 2 below.

TABLE 2
Nominal CCT Color Chart

| Nominal | Target CCT and | Target Dᵤᵥ |
|---|---|---|
| CCT | tolerance (K) | and tolerance |
| 2700° K | 2725 ± 145 | 0.000 ± 0.006 |
| 3000° K | 3045 ± 175 | 0.000 ± 0.006 |
| 3500° K | 3465 ± 245 | 0.000 ± 0.006 |
| 4000° K | 3985 ± 275 | 0.001 ± 0.006 |
| 4500° K | 4503 ± 243 | 0.001 ± 0.006 |
| 5000° K | 5028 ± 283 | 0.002 ± 0.006 |
| 5700° K | 5665 ± 355 | 0.002 ± 0.006 |
| 6500° K | 6530 ± 510 | 0.003 ± 0.006 |
| Flexible CCT | T ± ΔT | Dᵤᵥ ± 0.006 |
| (2700-6500° K) | | |

The chromaticity tolerances specified are depicted as quadrangles rather than ellipses on the chromatic diagram. These quadrangles correspond to approximately a seven-step MacAdam ellipse on the CIE 1931 Chromaticity Diagram as shown in FIG. 5.

US DOE Energy Star has recognizes CCTs of 2700° K, 3000° K, 3500° K, 4000° K, 4500° K, 5000° K, 5700° K, and 6500° K for indoor LED luminaries for residential and commercial applications.

The Color Rendering Index (CRI), also known as the color rendition index, is a measure of the degree of color shift objects undergo when illuminated by the light source as compared with those same objects when illuminated by a reference or natural light source of comparable color temperature. Reference IESNA Lighting Handbook, Ninth Edison, Copyright© 2000, Glossary of Lighting Terminology, page G-7. ANSI_NEMA_ANSLG C78.377-2008 Specification for the Chromaticity of Solid State Lighting (SSL) Products.

The CRI as a characteristic of SSL products is taken to mean the “General CRI” identified as Ra in CIE 13.3:1995 “Method of measuring and specifying color rendering properties of light sources”, 1995. The General Color Rendering Index Ra is calculated in accordance with CIE 13.3-1995, “Method of Measuring and Specifying Colour Rendering Properties of Light Sources”. It is the arithmetic mean (i.e., average) of the specific color rendering indices for each test color and is usually referred to simply as the CRI value of a test illuminant. However, CIE Technical Report 177:2007, Color Rendering of White LED Light Sources, states, “The conclusion of the Technical Committee is that the CIE CRI is generally not applicable to predict the color rendering rank order of a set of light sources when white LED light sources are involved in this set.” This recommendation is based on a survey of numerous academic studies that considered both phosphor-coated white light LEDs and red-green-blue (RGB) LED clusters.

Most of these studies involved visual experiments where observers ranked the appearance of illuminated scenes using lamps with different CRIs. In general, there was poor correlation between these rankings and the calculated CRI values. In fact, many RGB-based LED products have CRIs in the 20s, yet the light appears to render colors well. Reference US Department of Energy EERE, LED Measurement Series: Color Rendering Index and LEDs Publication, January 2008.

US DOE Energy Star Program Requirements for SSL Luminaries, V1.0, dated Apr. 9, 2007, has defines a nominal CRI >75 for indoor LED luminaries for residential and commercial applications. Table 3 provides a summary of very general accepted minimum values for CRI for LED technology.

TABLE 3
LED Industry CRI Values
LED Industry CRI Values

| | Warm | Neutral | Cool |
|---|---|---|---|
| CCT | 2700-3300° K | 3300 K-5000° K | 5000° K+ |
| CRI nominal | 85 | 80 | 75 |

### SUMMARY

A method of producing color-consistent LED light sources and the produced LED light source group is described herein. The method may incorporate binning, testing, grouping (sorting), labeling, and kitting. The method is provided to ensure LED light source products provide some degree of color consistency between RWLs within fixtures. In particular, but not limited, to color consistency between side by side aircraft reading, work, and task lights in support of MacAdam ellipse assumptions.

A method is provided for preparing a plurality of groupings of light-emitting diode (LED) lights, where each grouping comprises a plurality of LEDs that fall within a specified color range from respective target x, y color points, the method comprising: receiving a source group of LEDs from a supplier, the source group having a specified color range; measuring a color value for each LED in the source group with a color sensor; storing the measured color value for each LED in the source group along with a unique LED identifier; creating a first grouping of LEDs within the specified color range from a first target x, y color point by identifying a plurality of LEDs from the stored color values that fall within the specified color range; creating a second grouping of LEDs within the specified color range from a second target x, y color point that is different from the first target x, y color point by identifying a plurality of LEDs from the stored color values that fall within the specified color range.

The method in one embodiment comprises applying a physical or virtual said unique identifier related a first LED falling within the first grouping of LEDs to the first LED or a housing holding the first LED; and applying a physical or virtual said unique identifier related a second LED falling within the second grouping of LEDs to the second LED or a housing holding the second LED.

The method in another embodiment comprises assembling a first lighting assembly utilizing the first grouping of LEDs; and assembling a second lighting assembly utilizing the second grouping of LEDs.

A light-emitting diode (LED) system is also provided, comprising: a first LED lighting panel; and a second LED lighting panel; wherein each of the first and second LED lighting panels comprise: a plurality of LED lights, each having an LED and a unique identifier that is associated with a measured color value; wherein the plurality of LED lights for the first LED lighting panel comprise a first grouping of LEDs within a specified color range from a first target x, y color point, and the plurality of LED lights for the second LED lighting panel comprise a second grouping of LEDs within a specified color range from a second target x, y color point that is different from a first target x, y color point.

### DESCRIPTION OF THE DRAWINGS

Various embodiments of the invention are illustrated in the drawings:

FIG. 1 is a graph that includes a CIE 1931 chromaticity tolerance example;

FIG. 2 is a CIE 1931 chromaticity diagram with ellipses;

FIG. 3 is a CIE 1931 chromaticity diagram with the Planckian or black body locus;

FIG. 4 is a 1976 chromaticity diagram, with blackbody locus and isothermal CCT lines;

FIG. 5 is a 1976 chromaticity specifications of SSL products;

FIG. 6 is a graph illustrating Luxeon Rebel white general binning;

FIG. 7 is a graph illustrating Luxeon Rebel white ANSI binning 2009;

FIG. 8 is a graph illustrating Luxeon Rebel illumination ANSI 1/16th Micro Binning 2010;

FIGS. 9A and 9B are graphs illustrating 4000° K and 3000° K sample distributions respectively;

FIG. 10 is a graph illustrating the current rebel 3000° K bin with target point and 1.5-step ME;

FIG. 11 is a graph illustrating the current rebel 4000° K bin example with target point and 1.5-step ME;

FIG. 12 is a graph illustrating the current rebel 6000° K bin example with target point and 1.5-step ME;

FIG. 13 is a graph illustrating LED selection and binning for a 2700° K—16 sub-bin background;

FIG. 14 is a graph illustrating LED selection and binning for a 4000° K—16 sub-bin background;

FIG. 15 is a graph illustrating LED selection and binning for a 5000° K and a 5700° K—16 sub-bin background;

FIG. 16 is a graph illustrating LED binning for a 3000° K 7H bin at 3 SDCM;

FIG. 17 is a graph illustrating LED binning for a 3000° K 7H bin at 6.5 SDCM;

FIG. 18 is a graph illustrating LED binning for a 4000° K 5A bin at 3 SDCM;

FIG. 19 is a graph illustrating LED binning for a 4000° K 5A bin at 6.5 SDCM;

FIG. 20 is a graph illustrating LED binning for a 6000° K WO bin at 3 SDCM

FIG. 21 is a graph illustrating a hypothetical bin requirement for 3 SDCM (bin overlay);

FIG. 22 is a graph illustrating a hypothetical bin requirement for 3 SDCM (bin overlay);

FIG. 23 is a graph illustrating an example of a measured LED grouping;

FIG. 24 is a graph illustrating a sub-grouping of two sub-groups;

FIG. 25A is a graph illustrating a plurality of LED groupings and sub-groupings to ensure coverage of the bin and manufacturer's tester tolerance;

FIG. 25B is a graph illustrating variance associated with an LED, an LED light with one core lens and target distance, and an LED light with all lenses and target distances;

FIG. 26A is a bottom perspective view of an exemplary RWL;

FIG. 26B is a top perspective view of the exemplary RWL;

FIG. 26C is a side view of the exemplary RWL, including identifying bar code information

FIG. 26D is an exploded perspective view showing various components, including optional ones, making up the RWL;

FIG. 27 is a plan view illustrating dimensions and layout of an exemplary overhead panel arrangement;

FIG. 28 is a plan view illustrating various overhead panel arrangements;

FIG. 29 is a plan view illustrating the spacing on an exemplary 3-unit lateral panel and a center 4-unit center panel; and

FIG. 30 is a perspective top view of an exemplary PSU 40.

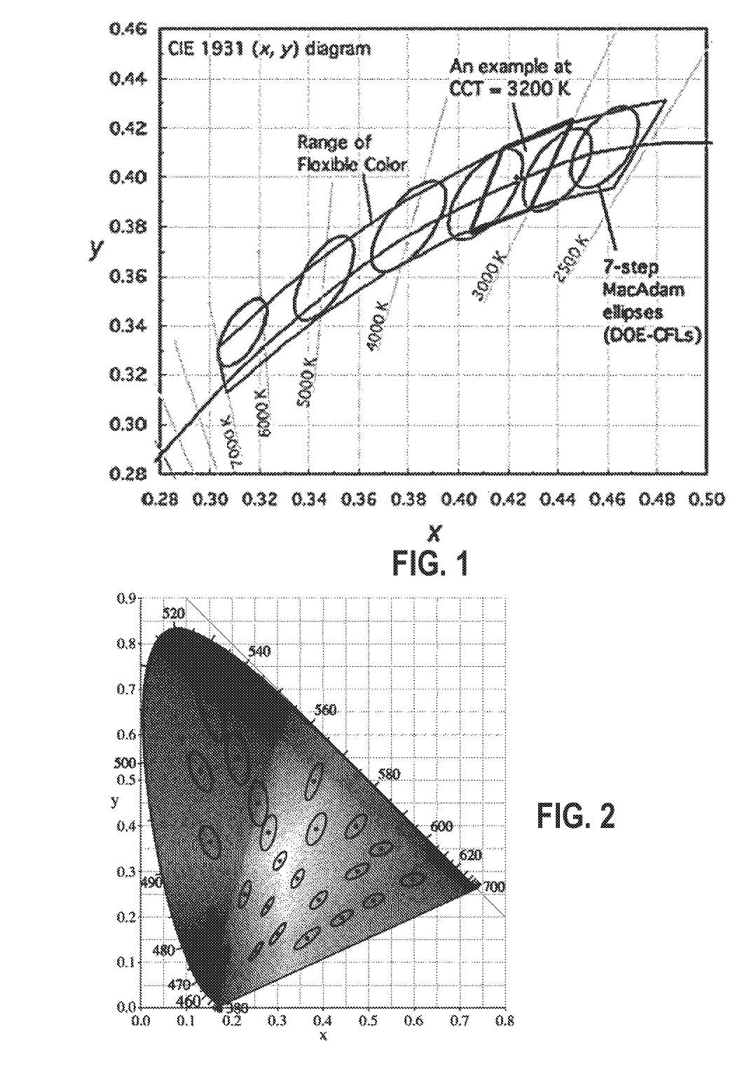

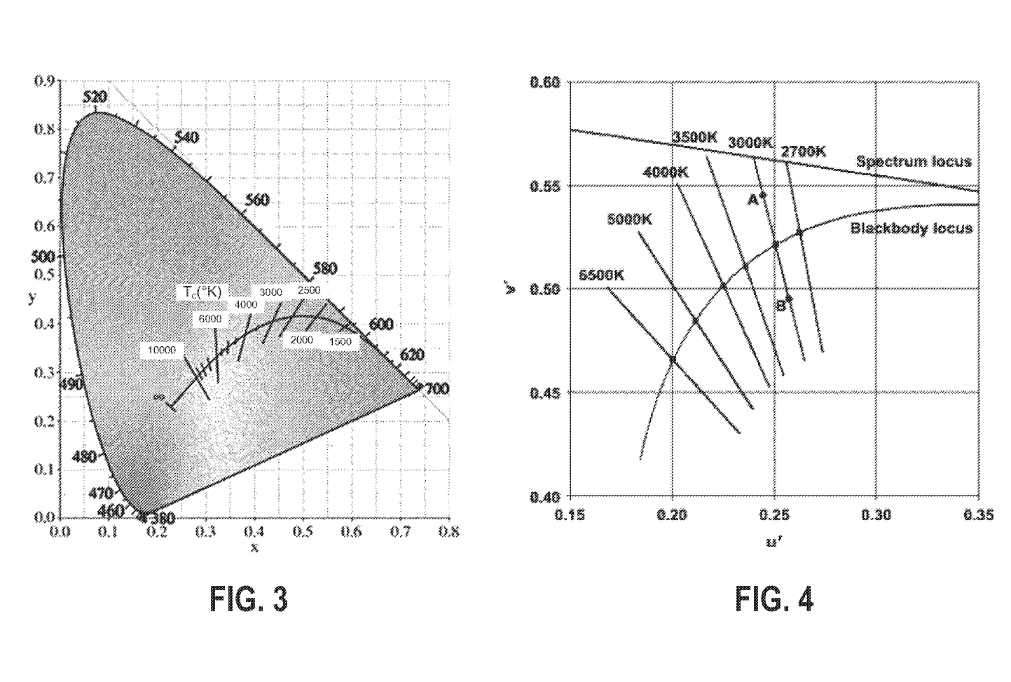

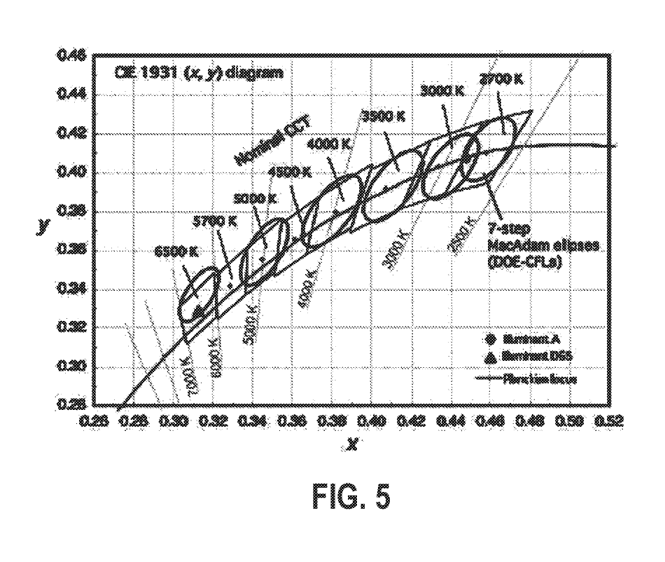

### DETAILED DESCRIPTION OF THE EMBODIMENTS

### Binning, Testing, Grouping

The method for producing a light grouping as described herein initially begins with the binning, testing, and grouping of the LEDs to ensure colors used in a light group do not vary in a detectable amount to the human eye.

In an embodiment of the invention, the color coordinates on the CIE 1931 chromaticity diagram between installed RWLs are less than or equal to three standard deviations of color matching (SDCM) or 1.5 MacAdam ellipse diameters at entry into service. IEC-60081, Edition 5.1, Page I-8, Paragraph 1.5.6 Photometric characteristics, subparagraph (b) suggests that the initial reading of the chromaticity coordinates x and y of a lamp should be within five SDCM from the rated values. IEC-60081, Edition 5.1, Annex D, page D-2, paragraph D.1 General states the specific chromaticity coordinate tolerance areas are defined by MacAdam ellipses of five SDCM. Also, according to an embodiment, nominal CCT values are considered to be 3000° K for warm, 4000° K for neutral and 5700° K for cool. Nominal CRI values are considered to be ≧85 for warm, ≧75 for neutral and ≧70 for cool, although any of these definitions can be changed.

The ability to meet the color requirements involves: 1) the LED selection and exclusive groupings with the LED supplier, 2) test methodology, and 3) sorting and labeling and controls.

The sorting aspect can be broken down into three distinct areas: 1) sorting of the LEDs into bins by the manufacturer (manufacturer bin sort); 2) presorting at a lens level (lens-level presort; and 3) final sorting at PSU level (PSU sort).

The relationship of the manufacturer bin sort to the inventive design is described in the following paragraphs. A proper selection and use of exclusive groupings with an LED supplier is the first aspect for meeting color requirements. The LEDs selected, by way of example only, may be Philips Lumileds Luxeon ES and the Rebel LED family (see Table 4 below). In an exemplary embodiment, CCT values are chosen that have specific x, y custom color coordinates with a tolerance and a resultant CRI.

TABLE 4
LED Selection and Various Associated Parameters
LED Selection and Key Parameters

| | LED | | | Nominal | Min | Typ | Color |
|---|---|---|---|---|---|---|---|
| Color | Family | Brand | Die Size | CCT (°K) | CRI | CRI | Technology |
| Warm | LXM8 | Luxeon Rebel | 1 mm | 3000 | 80 | 85 | Lumiramics |
| Warm | LXH8 | Luxeon ES | 2 mm | 2700 | 80 | 85 | Lumiramics |
| Warm | LXH8 | Luxeon ES | 2 mm | 3000 | 80 | 85 | Lumiramics |
| Neutral | LXM3 | Luxeon Rebel | 1 mm | 4000 | 80 | 85 | Industry |
| | | | | | | | Standard |
| Neutral | LXH7 | Luxeon ES | 2 mm | 4000 | 70 | 75 | Lumiramics |
| Cool | LXW8 | Luxeon ES | 2 mm | 5000 | 80 | 85 | Industry |
| | | | | | | | Standard |
| Cool | LXML | Luxeon Rebel | 1 mm | 5700 | 65 | 70 | Industry |
| | | | | | | | Standard |

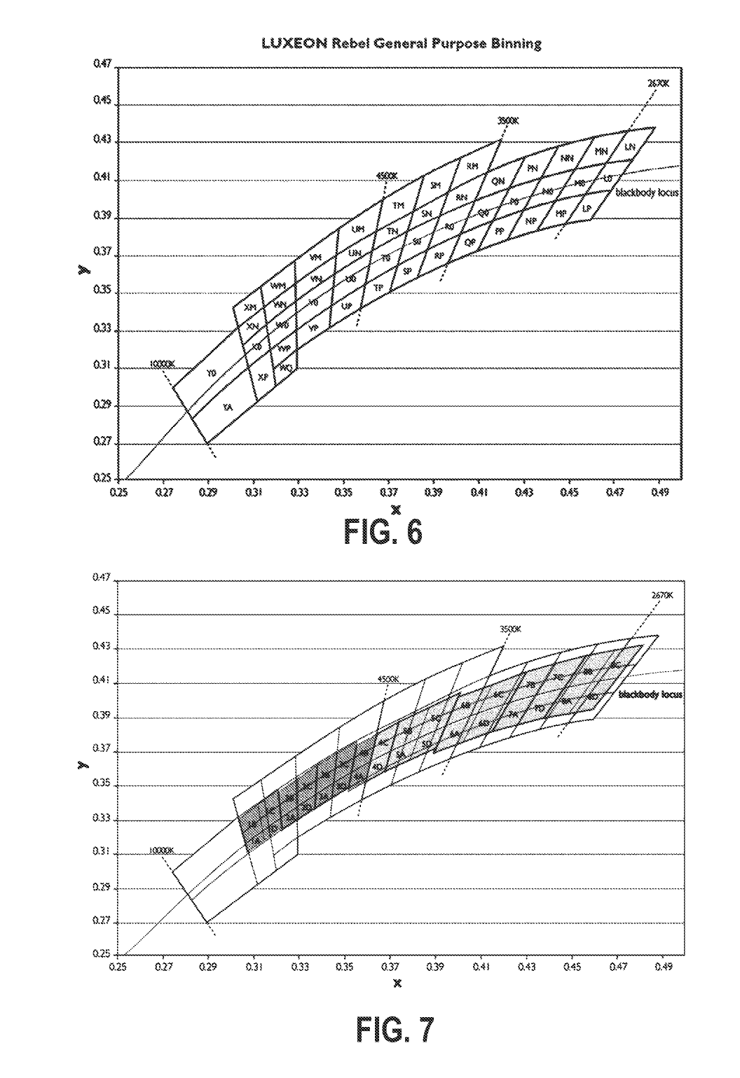

In order to provide a level of control, LED supply chain management is utilized. In this procedure, the manufacturer and supplier of LEDs agree to a level of binning control and applicable product family chosen for each CCT. By way of example, Philips Lumileds Luxeon Rebel was one of the first organizations to adapt the ANSI C78.377-2008 Specifications for the Chromaticity of Solid State Lighting Products binning structure and to introduce this Standard into its LED solutions. The LED industry, prior to the ANSI standard, operated mainly on company/product specific or self-driven bin structure and naming conventions. The Philips Luxeon Rebel white general binning scheme is illustrated in FIG. 6.

Once the Industry adopted the ANSI standard for LED technology, Philips Lumileds was one of the first to adopt the Bin structure and produce the Luxeon Rebel in ¼ Bin quadrants. This Bin structure is depicted in FIG. 7.

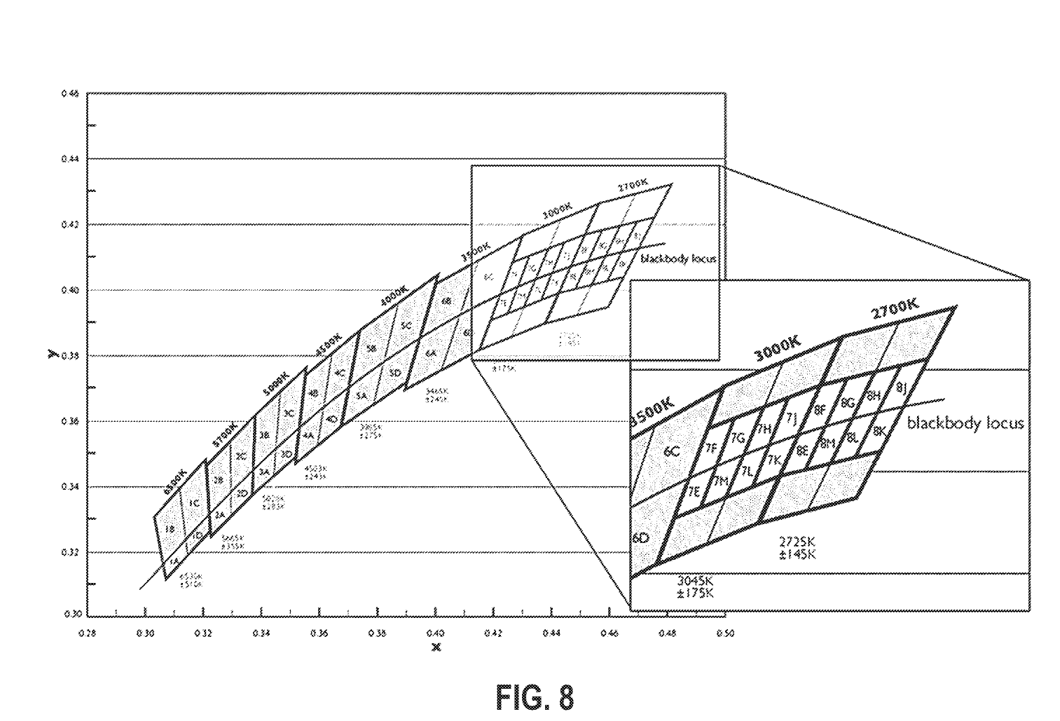

Furthermore, Philips Lumileds was an industry leader in offering binning, for the Luxeon Rebel, down to the 1/16th of a standard ANSI bin hence allowing tighter control and color consistency in LED illumination products. Such a level of control allows designs to provide very strong color consistency within single LED lighting systems. An example of 1/16th micro binning can be found in FIG. 8, which shows Luxeon Rebel Illumination ANSI 1/16th Micro Binning 2010.

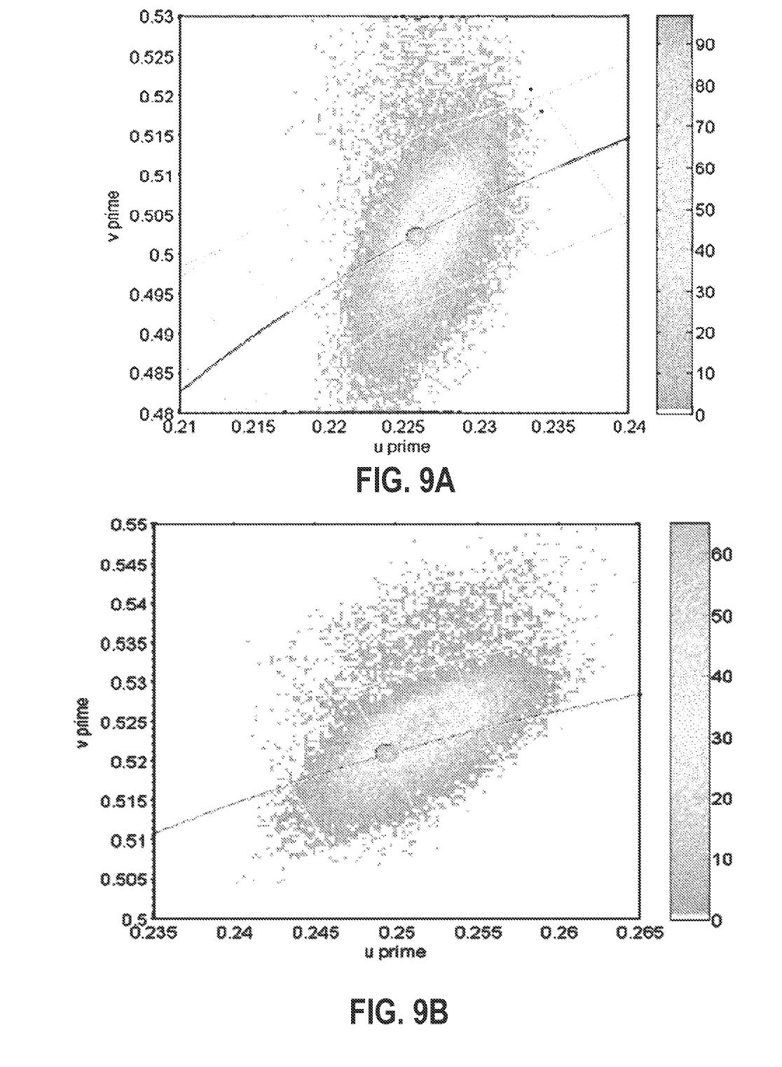

Although Philips Lumileds Micro Bins to an ANSI standard, there are some applications where customer specification requires color consistency that exceeds current industry standard and production processes. In these cases, alternate or application specific manufacturing and supply chain solutions intended to fulfill the needs of the color requirements and customer driven design can be utilized. For example, a point cloud distribution of associated CCT requirements to account for production process trends could be used to select optimal x, y color targets for associated single LED designs. Examples of the 4000° K and 3000° K distributions are illustrated in FIGS. 9A and 9B respectively.

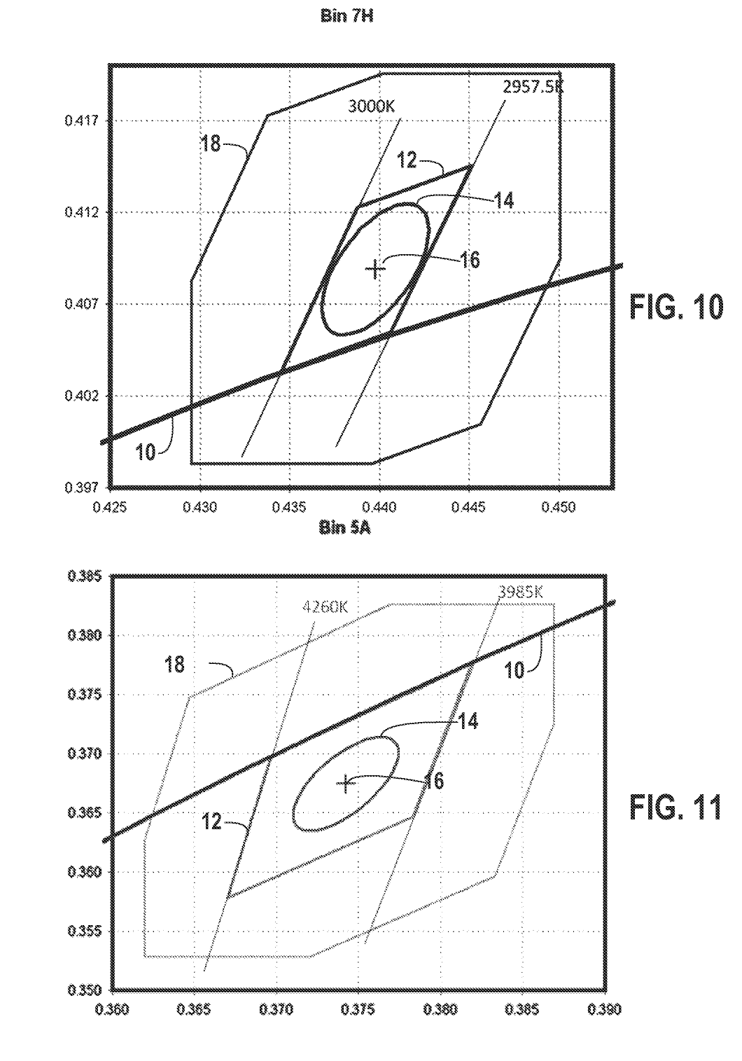

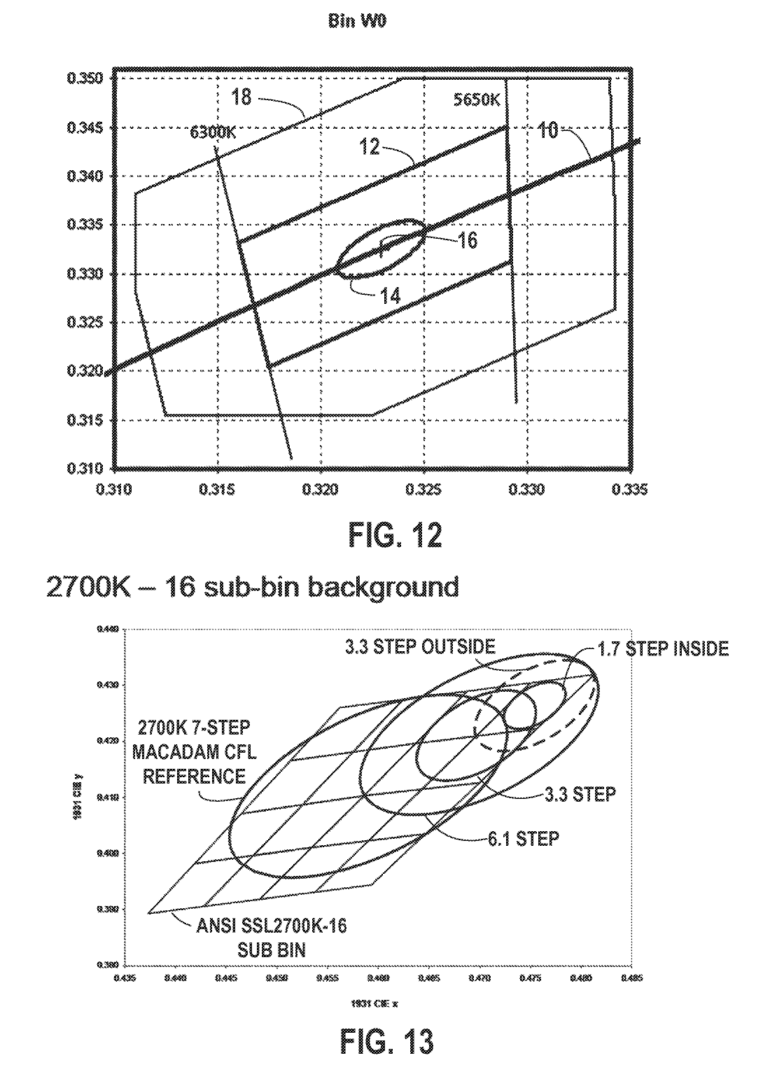

Examples of the current specification exceeding industry standards and supplier micro binning structures can be further realized in the following charts, which outline various color temperature target points with associated micro bins offered in volume production. In FIGS. 10-12, the blackbody curve 10 borders a parallelogram that represents a bin 12 having an inner ellipse 14 that is an adjusted ME, about a center point 16. The outer polygon 18 represents a bin limit. FIG. 10 is a current Rebel 3000° K bin example with target point and 1.5-step ME. FIG. 11 is a current Rebel 4000° K bin example with target point and 1.5-step ME. FIG. 12 is a current Rebel 5-6000° K bin example with target point and 1.5-step ME.

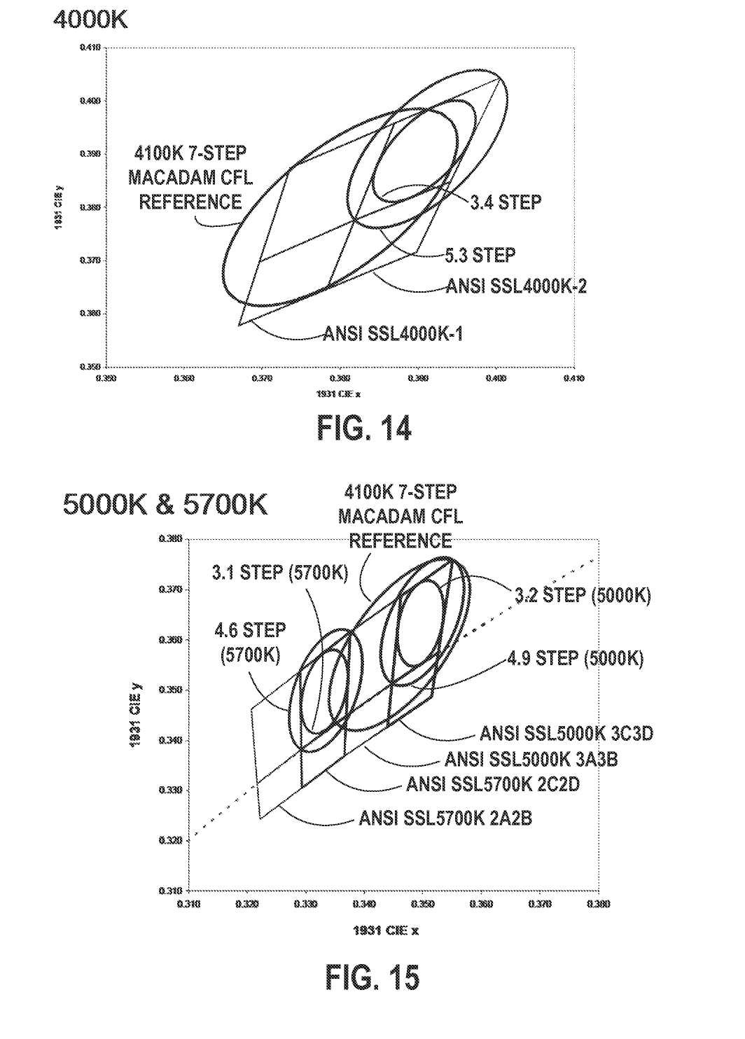

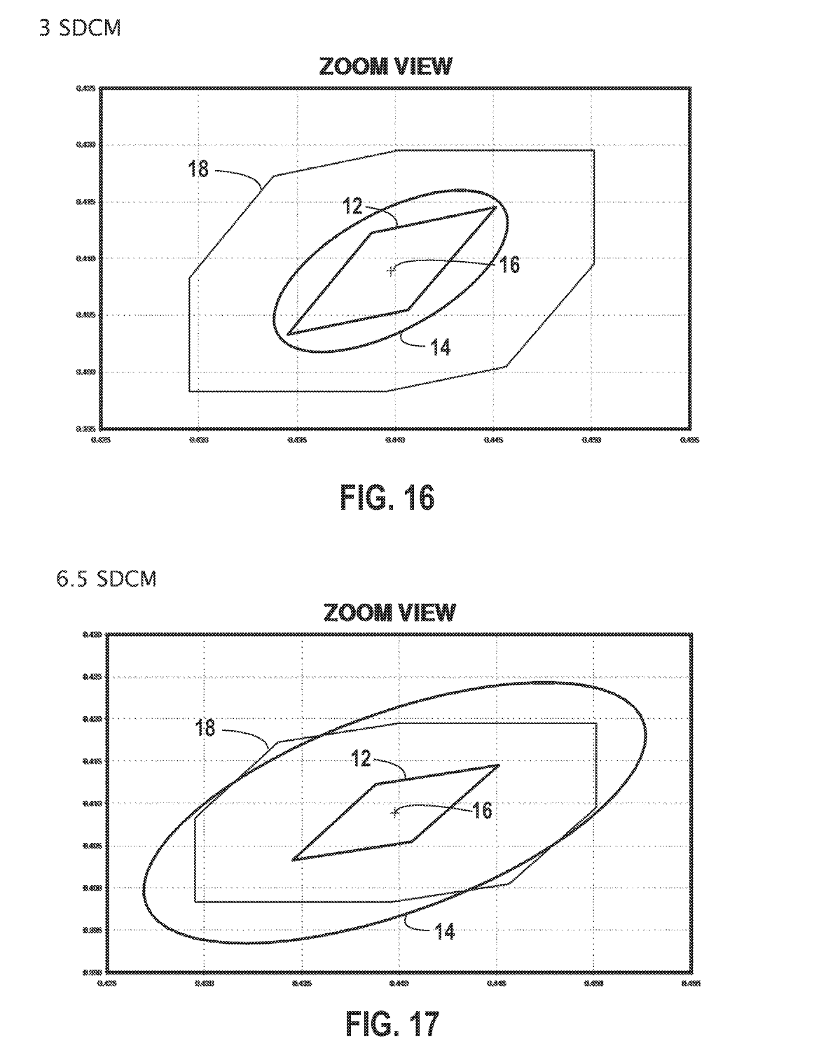

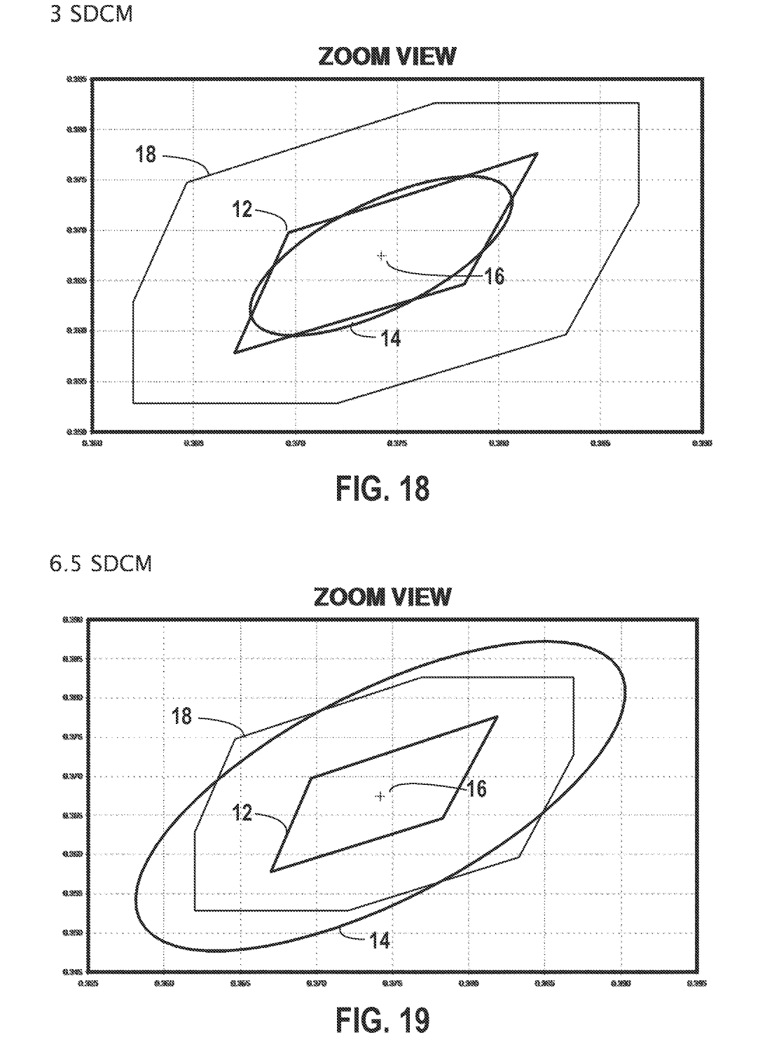

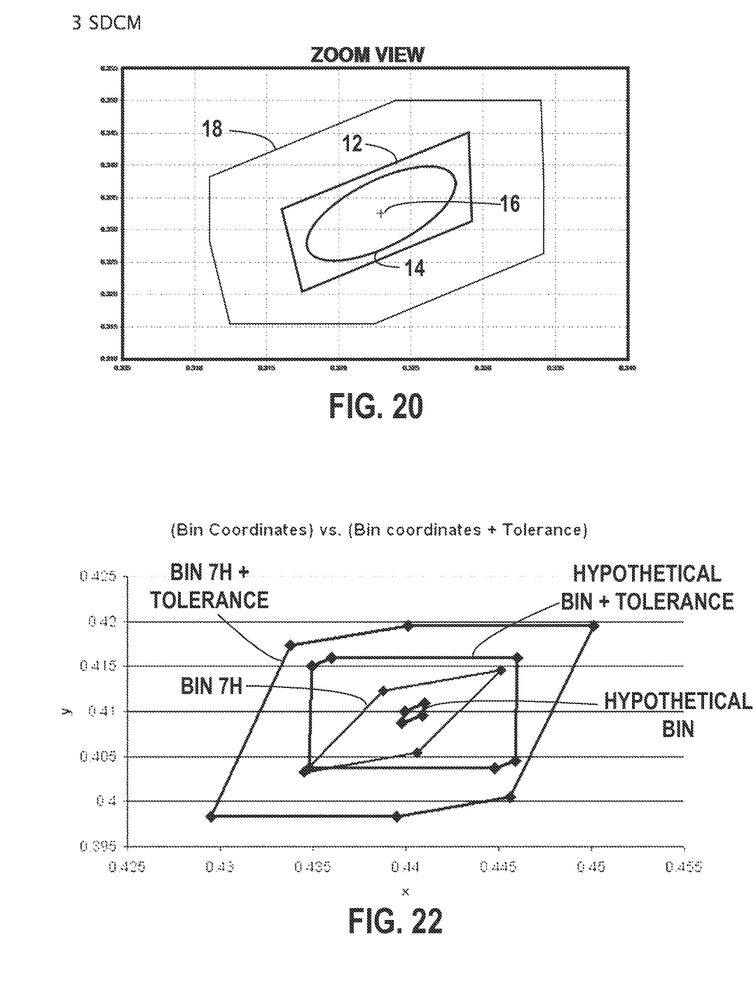

FIGS. 13-20 illustrate detailed aspects of the binning FIG. 13 illustrates a 2700° K bin with a 16 sub-bin background. FIG. 14 illustrates a 4000° K bin with a portion of the 16 sub-bin background. FIG. 15 illustrates a 5000° K and a 5700° K bin with a portion of the 16 sub-bin background. FIG. 16 illustrates a 3000° K bin (bin 7H) at 3 SDCM. FIG. 17 illustrates a 3000° K bin (bin 7H) at 6.5 SDCM. FIG. 18 illustrates a 4000° K bin (bin 5A) at 3 SDCM. FIG. 19 illustrates a 4000° K bin (bin 5A) at 6.5 SDCM. FIG. 20 illustrates a 6000° K bin (bin WO) at 3 SDCM.

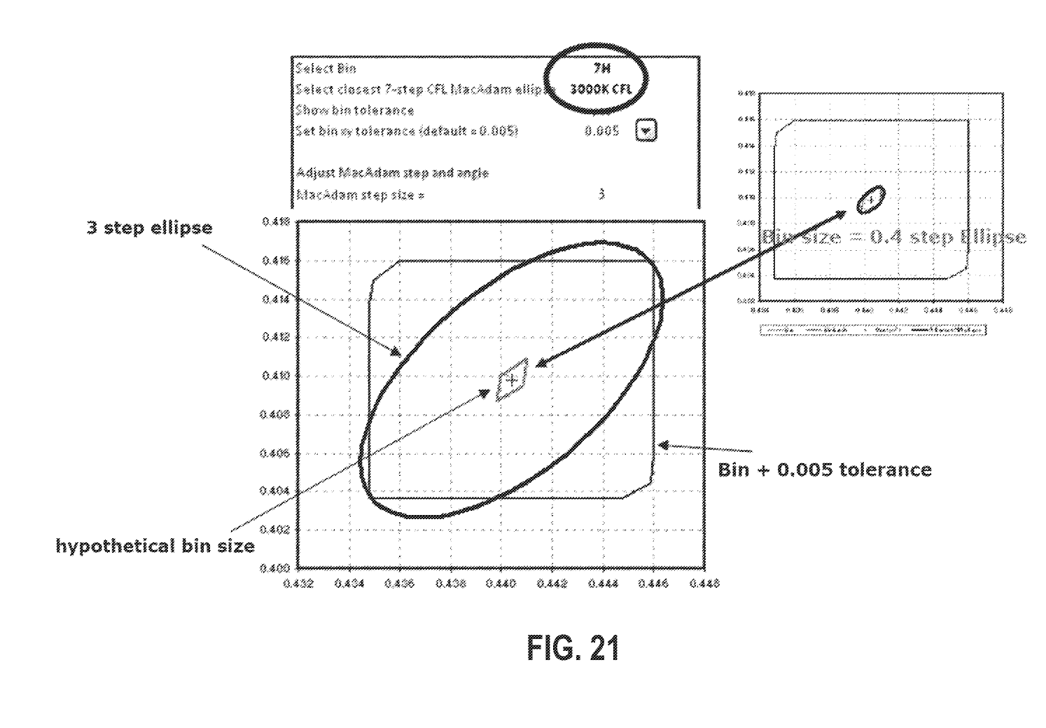

FIG. 21 presents a graph in which an arbitrary hypothetical bin requirement for 3 SDM is specified. FIG. 22 illustrates a bin overlay with the hypothetical bin. It can be seen, however, that even one of the tightest high volume manufacturing processes coupled with industry standard binning structures may not satisfy a 1.5-step MacAdam Ellipse requirement when positioning an x, y target point in the middle of the ANSI ¼, Micro 1/16^{th} and Cool White General Color Bins. Thus, alternative methods and process controls are required.

Further control procedures are utilized to target areas of high volume distribution within specified bins, which allow the realization of production parts with target x, y color points and a 1.5-step MacAdam ellipse tolerance within the associated color specification.

### LED Variability Compliance Validation

In order to control the variability of the LEDs, a Test Procedure (TP) can be performed on each RWL and include final product color compliance validation through the following method.

First, the color chromaticity (x, y coordinates) is measured using, e.g., a test setup as illustrated described below, in which the following calibrated test equipment may be used.

TABLE 5
Exemplary Test Configuration

| | |
|---|---|
| Multimeter | Fluke 79, Fluke 87 Series Multimeters or equivalent |
| Light Meter | Minolta CL-200 or equivalent to measure RWL |
| | illuminance and color |
| IR/Dielectric | Quadtech Guardian 1030 or equivalent |
| Meter | |
| Scale | Ohaus EC Series or equivalent |
| Measurement | Mitutoyo Series or equivalent |
| Caliper | |
| DC Power Supply | GW Instek GPS Series Power Supply or equivalent |
| Test Fixture | Fixture that holds the RWL (within a black-body |
| | housing) |
| Test Harness | Harness that provides wiring to the test fixture- |
| | preferably, this represents the type of wiring found in |
| | the vehicle (e.g., replicates that found on an airplane), |
| | although it does not have to meet rigorous DOT |
| | standards |
| Photometric | |
| Measuring Tool | |

An RWL is placed in a fixture, turned on, and the illuminance and color are measured by the light meter by providing a constant power to it. The measured values are preferably recorded into a database correlated to a serial number for each RWL, and optionally displayed. The values, however could alternately or additionally be stored in a memory of the RWL itself so that the RWL always contains its measured information. This could assist in the event a replacement RWL is required.

The general procedure is that an RWL is placed within the test fixture and the test harness is attached. Power is then applied to the RWL and the photometric measuring tool/sensor reads the light output of the RWL. The measured values are then stored associated with a unique identifier of the RWL. Such an identifier can be a physical identifier (such as one printed on a label or sheet of paper), or a virtual identifier (stored in a database). Additionally, some form of a pass-fail signal or other means could be provided as well. The sensor should be calibrated once or twice a year, or as required by the equipment manufacturer and rate of use and thus make accurate color measurements to within ±0.25 step MacAdam ellipse relative to the target color point(s).

In one embodiment, a “golden unit” (an illumination source with a know/desired color characteristic) that serves as some form of a standard could be measured along with the RWL unit being tested (immediately sequential to or in an adjacent chamber). If the golden unit and the test unit are measured by the same test unit, then any variance between the test units can be eliminated. Thus, the comparison can be made against an actual physical standard model, or it can simply be made with a mathematical model on the computer.

The database that stores the data can be any known database, or even a simple Excel spreadsheet or comma delimited text file, for ease of exchange.

In a preferred embodiment, each RWL can be labeled with nomenclature that may distinguish between possible 1.5-step MacAdam ellipse groupings for each CCT. A 1.5-step MacAdam ellipse grouping is preferred for all lights in a given PSU panel group (G₁), e.g., with 3 lights: G₁L₁, G₁L₂, G₁L₃, but another panel group (G₂) could have LEDs that differ by more than a 1.5-step MacAdam ellipse from those in the first panel group, as long as the ones in the second panel group didn't vary amongst themselves by more than a 1.5-step MacAdam ellipse. It is also important to note that the variance amounts should incorporate all LED lights of an entire PSU, and not just those immediately adjacent to one another.

In addition to specifying an intra-panel maximum variance, it is also possible to specify an inter-panel maximum variance, and such a variance could be dependent on the relative locations of the various PSUs. For example, a second PSU immediately adjacent to a first PSU might require less variance between lights than the second PSU being located in a completely different area of the cabin. Furthermore, an overall vehicle variance for PSUs could also be specified. A number of different types of variances can be considered as well. For example, a light-to-light or a PSU-to-PSU variance can be identified along with a permitted variance for any light and/or PSU that can be seen at a same time by a person.

Specific determinations could be made about the visibility of individual LED lights and/or PSU units that are visible from a particular spot (or reflections of lights from surfaces that are visible from a particular spot), and permitted variances could be established based on these particular groupings of lights (i.e., groupings based on visibility from a particular vantage point). The overall notion is that the groupings (and these can be any arbitrary defined groupings of lights) and associated variances of lights permitted within groupings can be established based on any number of criteria, particularly, but not limited to, visibility (direct or indirect/reflected) criteria and relative location.

### Grouping

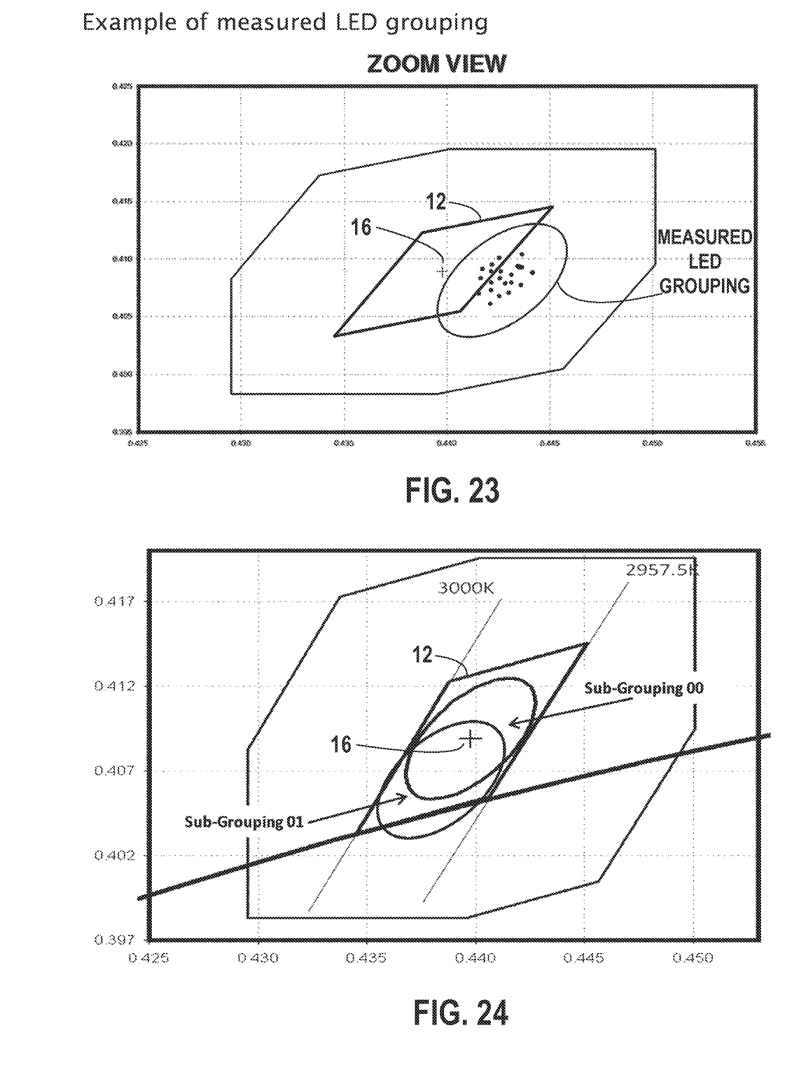

An example in FIG. 23 and FIG. 24 shows possible LED groupings and sub-groupings utilizing the LXH8 Luxeon ES with a projected high LED production yield and LED point cloud distribution within a given bin for the PSU sorting. This represents two possible RWL warm white sub-groupings. Labels (including barcodes or other machine-readable labels) may also be used that include, e.g., part number, unique serial number, assembly revision, inspection information, and other relevant information. It is possible to provide a grouping/sub-grouping identifier on the label as well.

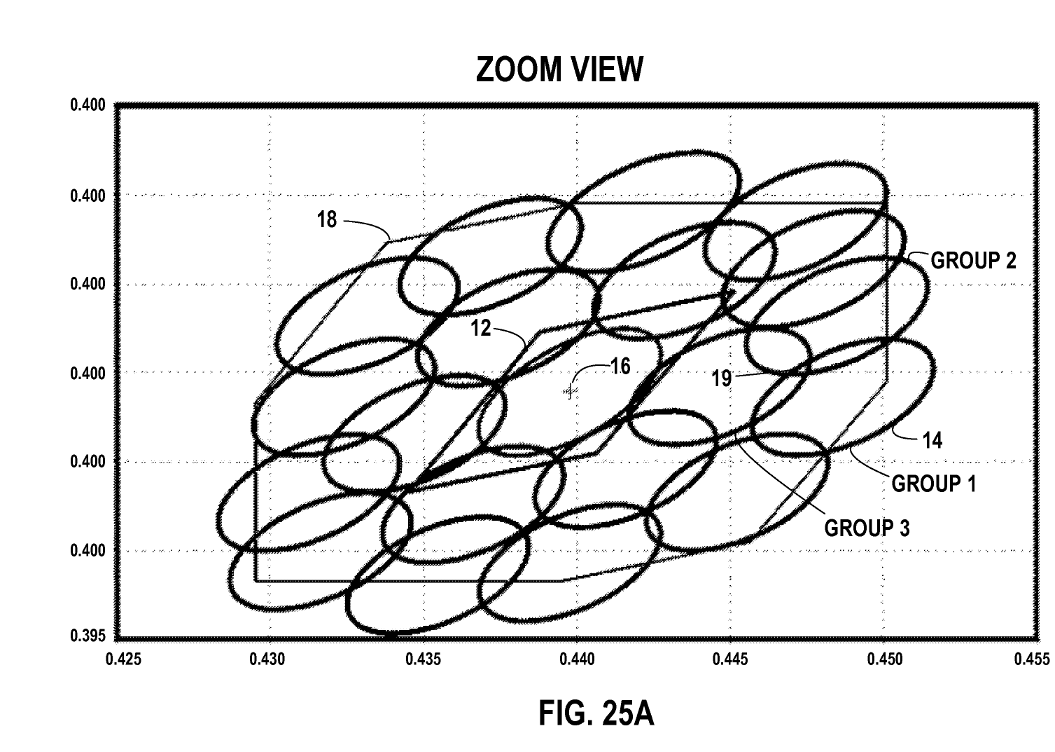

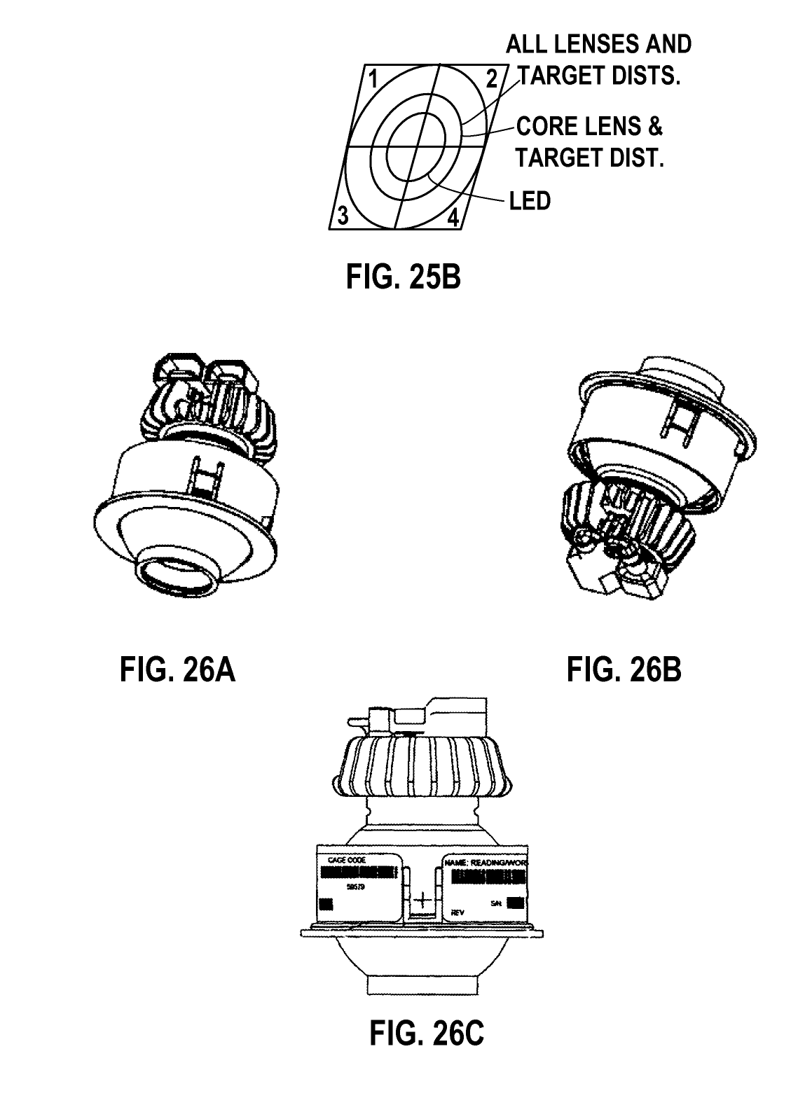

Also, additional groupings may be utilized to include the manufacturer's tester tolerance as shown in FIG. 25A. In this example a plurality of 1.5 step diameter MEs 14 are shown for an example bin ensuring entire coverage of the bin and manufacturer's tester tolerance. Each one of these ellipses represents possible groupings of LEDs that may be supplied on any given reel or tube, etc. Each one of those groupings may be given a designation such as group 00, 01, 02, etc., up to NN groups. During the final TP tests performed on the reading light, the x, y color coordinates are measured by a meter and this info can be recorded and applied to a label which can then be affixed to the reading light as shown above. This may also be done automatically via the database that records the color coordinates and associates the serial number with the RWL, and may be included along with the RWL's serial number on the bar code as well.

After having measured and recorded the characteristics of each LED, and associating a serial number with the LED, a kit of LEDs for a particular panel can be assembled by identifying and providing only those LEDs that fall within a 1.5-step MacAdam ellipse of one another.

In one advantageous embodiment, the grouping/subgrouping assignment for the PSU sort need not be made at the time of measurement. For example, an RWL might be measured at the crosshairs shown in FIG. 24. As can be seen, such an RWL could be assigned to either sub-grouping 00 or sub-grouping 01. One embodiment permits assignment to a group or sub-group immediately after measurement (such an assignment could be based on which group's center the measurement is closest to, or could be based on inventory requirements or other manufacturing criteria, including real-time status, etc.) In FIG. 25, an RWL measuring within area 19, the intersection of groups 1-3, its membership could be assigned to any of these groups. Thus, the RWL might be usable in several different panels, even though the panels have differing RWL group numbers. Thus, a database of RWL color measurements can be maintained for possible PSU panel correlation as well as for return material authorization (RMA) purposes.

However, in another embodiment, it is not necessary to immediately designate the grouping after measurement. Rather, an inventory of RWLs can be created in which the RWLs all have x, y color coordinate data associated with them. Then, in response to particular work orders, the best groupings that meet the variance requirement can be created at this time. For example, an RWL located at the center of sub-grouping 01 above may be assigned to sub-grouping 00 if there is a shortage or other particular need for RWLs belonging to sub-grouping 00, even if the RWL is at an optimal position for sub-grouping 01.

Algorithms can be provided that could perform such optimization not just on a PSU-basis, but on the basis of an entire aircraft. For example, an aircraft-level work order might require sixty RWLs organized into twenty PSUs. An optimizing algorithm could examine the entire inventory of RWLs and, using combinatorial algorithms, find RWL groupings that satisfy the 1.5-step (or other predefined tolerance criteria) ME for each of the twenty PSUs—or, if the entire work order cannot be satisfied with existing inventory, a configuration that minimizes the additional RWLs needed could be prepared (and desired x, y color coordinates or bin information for the needed RWLs could be listed).

### Mechanical Layout

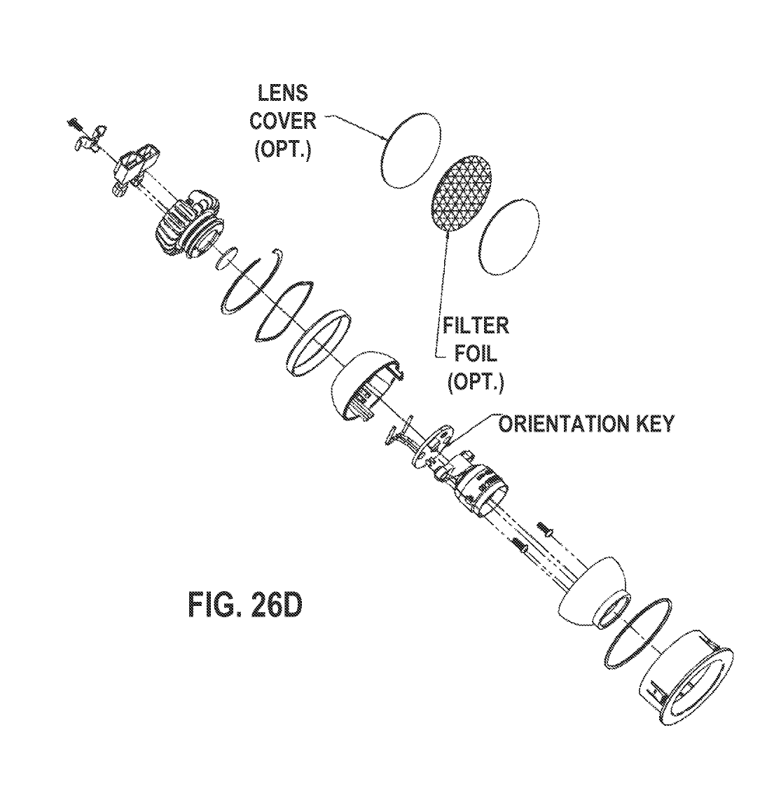

FIGS. 26A-D illustrate an exemplary RWL. FIG. 26A is a bottom perspective view of the RWL, and FIG. 26B is a top perspective view. FIG. 26C is a side view of an exemplary embodiment including identifying bar code information, and FIG. 26D is an exploded perspective view showing various components, including optional ones, making up the RWL. For example, the RWL may have a lens/filter cover that can color shift the output of the LED light that passes through it—in other words, it is possible that the RWL lens may shift the CCT and CRI of the source LED resulting in net CCTs that differ from those in the table above.

The RWLs are preferably tested in an assembled configuration, including any lenses or filters. In this way, any effects of color shifting created by the lenses/filters can be taken into account in the measurements. There can be a high variability in the amount of color shift that lenses/filters impart to a particular LED (as much as 400° K or more) due to, e.g., impurities, and so including the lenses/filters in the unit for measurement results in an end-product that minimizes color variance. The RWLs typically allows for a 3-5 mil lens to shift the color of the RWL.

However, it is also possible to measure the color of the RWLs without a lens/filter and then also measure the lens/filter color separately (storing data for both). Although this is a more time consuming method, it can provide greater flexibility in matching up RWLs and filters. For example, a particular RWL/LED and filter combination could potentially put the RWL outside of a particular target group. However, a separate filter having a different characteristic, when used on the same RWL could put the RWL back into the desired target group. Thus, it may be advantageous to track data of filterless RWLs and filter data separately.

The data logged samples can be tested and individually marked with a specific reference that can be used to trace an individual LED back to a specific RWL. The LEDs color can be evaluated for color correlation according to the requirements.

The following Table 6 exemplary compliance matrix summarizes specific parameters of the RWL and its noted compliance.

TABLE 6
Exemplary Reading Lights Compliance Matrix
RWL Requirements

| | | Color | | LED | | 1.5 |
|---|---|---|---|---|---|---|
| RWL | Lens Focal | (nominal)³ | | | Bin/ | MacAdam |
| Part Number | lengths (cm) | (K) | CRI | PN | Group | Ellipse^{1,2} |
| 5827-0BC-XX | 100, 150, 200 | 3000 | 85 | — | — | Compliant |
| 5827-1BC-XX | 100, 150, 200 | 4000 | 70 | — | — | Complaint |
| 5827-2BC-XX | 100, 150, 200 | 5700 | 65 | — | — | 1.5 or 2.0 |
| | | | | | | TBC |

Notes for Table 6 include: (1) for side by side (adjacent) reading lights; (2) LED manufacturers tester tolerances included; (3) component provider tester tolerances included; (4) final CCT and CRI for RWL TBC. The lens focal lengths represent the distance of an illuminated surface the LED light is intended to illuminate and at which the illumination properties of the lens are definitely met.

A lens-level presorting operation may be included as well, distinct from the manufacturer bin sort and the PSU sort. Such a sort can take into account various filters, diffusers, focus lenses, etc. that may be used on an LED light. Various values associated with the LED lights and possible variances may, e.g., be defined as illustrated in the following table.

TABLE 7
Values and Variances Associated with Temperature and Distance

| | Dist. 1 | Dist. 2 | Dist. 3 |
|---|---|---|---|
| Warm | V_{W1} | V_{W2} | V_{W3} |
| Neutral | V_{N1} | V_{N2} | V_{N3} |
| Cool | V_{C1} | V_{C2} | V_{C3} |

In one embodiment, it may be possible, using the lens-level and filtering sorting to associate a particular grouping. By way of example, after using a manufacturer's bin sort, an LED may be installed on a board and is intended to be used in an LED light that is neutral at Distance 1. However, the light might fail the testing in that configuration. Rather than discard the light as unusable, a new filter and/or lens could be used to vary the focal length or ultimate output color of the LED light. Further testing in a modified configuration could result in the LED light being acceptable for use in a warm configuration, or a cool configuration. The lens-level presort, or lens assembly level testing to determine which PSU or other arrangement a an LED light with lens/filter assembly works best with provides an advantageous solution to the organization of LED lights within the system. The LED light combination with its lensing/filters can be tested as a whole. Testing at different distances with different lenses and different filters could modify the attributes/characteristics of the light and hence its ultimate grouping association, or, the result of the testing might put it in a fourth quadrant/grouping, i.e., it is not assembled in a final configuration.

This sort level/analysis provides a further advantage. It can accommodate variation in color based on angle of light. It is well-known that different light frequencies disperse at different angles thorough a particular medium (e.g., as illustrated by creating a rainbow from white light using a prism). Depending on the light path, there may be a “color over angle” variance to the color, due to, e.g., the shape of an end cap lens placed on the LED. Thus, one cannot guarantee consistent color output in rings defining a particular angular distance. The LED lights thus can include a diffuser that can be utilized as a part of the measurements (and the measurements can be taken at the center point, a particular angle, a range of angles, etc., and these measurements can be associated with a particular LED light to help determine the ultimate grouping of the LED lights for PSU assembly.

FIG. 25B illustrates possible variance for an LED itself, the larger range for a particular core lens at a target distance, and the largest range for all lenses and all relevant target distances. The sort can thus allocate an LED light into one of the four illustrated quadrants/groups.

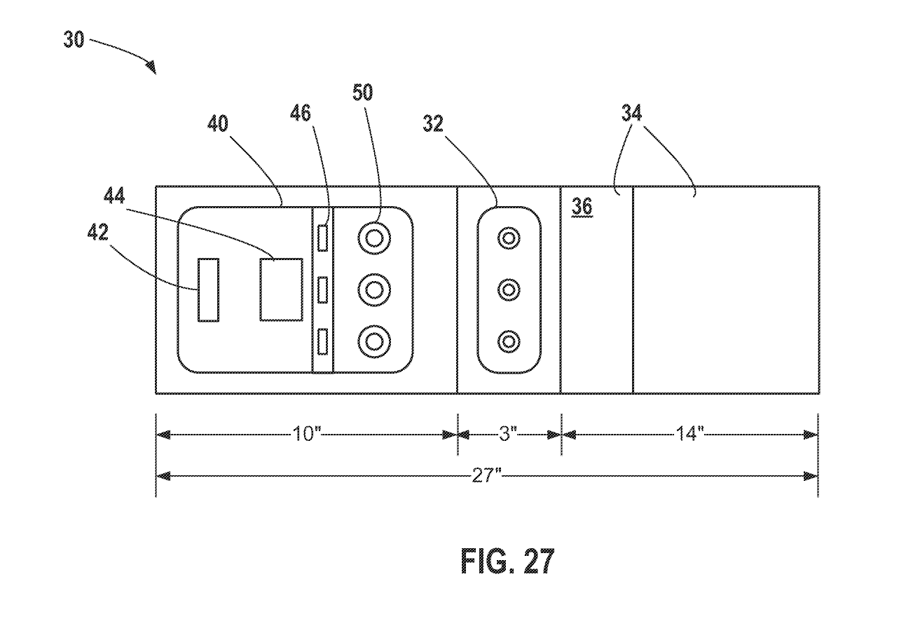

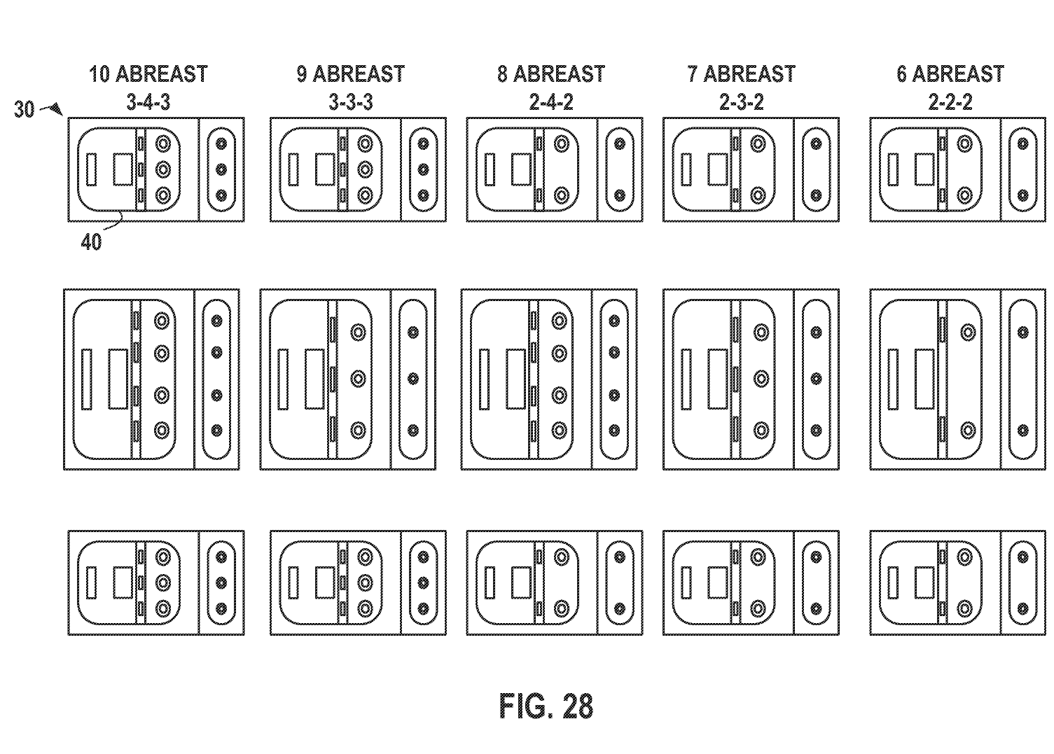

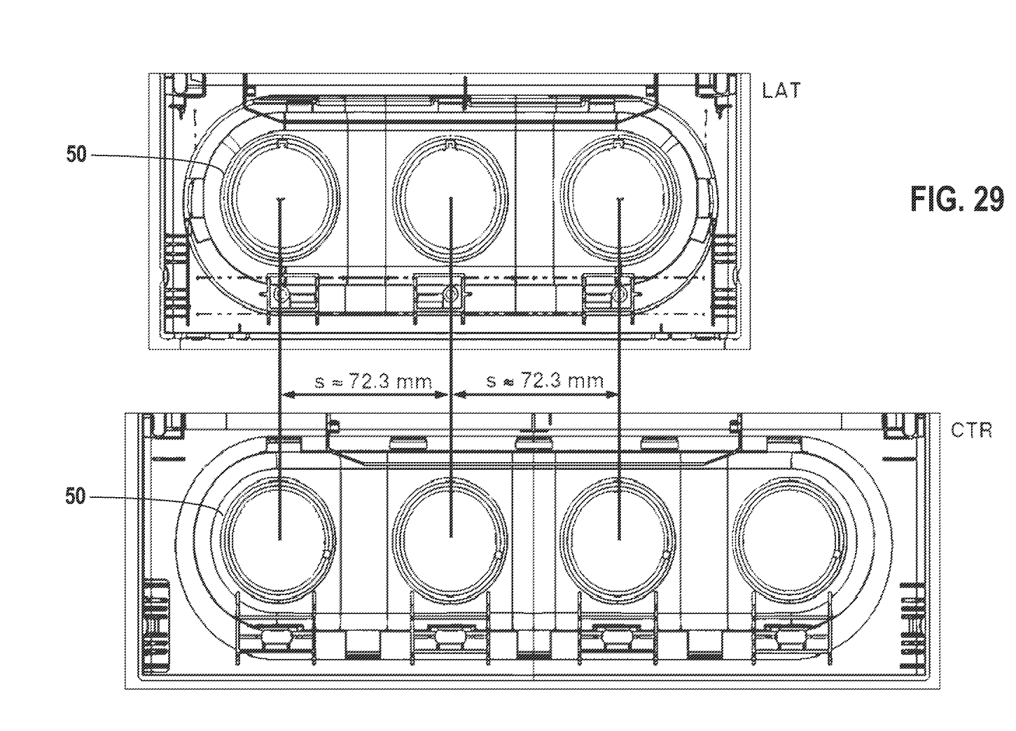

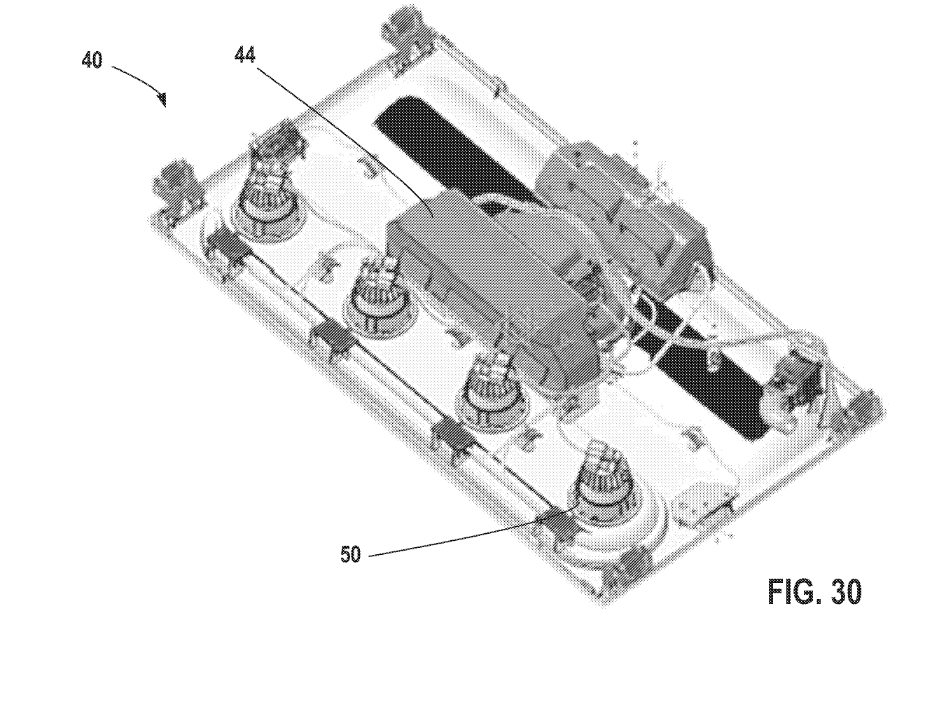

FIG. 27 illustrates dimensions and layout of an exemplary overhead panel arrangement 30 comprising a panel service unit PSU 40, recessed air nozzles 32, and an oxygen panel 34 with an oxygen masks lid 36. The PSU 40 comprises an NS/FSB 42, loudspeaker 44, flight attendant call button 46, and RWL 50. FIG. 28 illustrates various overhead panel arrangements 30 for various seating configurations on aircraft. FIG. 29 illustrates the spacing on an exemplary 3-unit lateral panel, and a center 4-unit center panel. FIG. 30 is a perspective top view of the PSU 40.

While the above described system and method can be used to control variance for a grouping of lights within a single PSU (i.e., an intra-PSU grouping), there is nothing that precludes a use of similar control methods for inter-PSU grouping. This could be done by specifying different center point and variance parameters for new groups, or could be done by providing a hierarchical grouping identification scheme. Also, specific values of threshold permitted variances have been used in the above. Although the values discussed and used are advantageous for the reasons related above, the invention encompasses different values than those discussed above in the examples.

The system or systems described herein may be implemented on any form of computer or computers and the components may be implemented as dedicated applications or in client-server architectures, including a web-based architecture, and can include functional programs, codes, and code segments. Any of the computers may comprise a processor, a memory for storing program data and executing it, a permanent storage such as a disk drive, a communications port for handling communications with external devices, and user interface devices, including a display, keyboard, mouse, etc. When software modules are involved, these software modules may be stored as program instructions or computer readable codes executable on the processor on a computer-readable media such as read-only memory (ROM), random-access memory (RAM), CD-ROMs, magnetic tapes, floppy disks, and optical data storage devices. The computer readable recording medium can also be distributed over network coupled computer systems so that the computer readable code is stored and executed in a distributed fashion. This media can be read by the computer, stored in the memory, and executed by the processor.

All references, including publications, patent applications, and patents, cited herein are hereby incorporated by reference to the same extent as if each reference were individually and specifically indicated to be incorporated by reference and were set forth in its entirety herein.

For the purposes of promoting an understanding of the principles of the invention, reference has been made to the preferred embodiments illustrated in the drawings, and specific language has been used to describe these embodiments. However, no limitation of the scope of the invention is intended by this specific language, and the invention should be construed to encompass all embodiments that would normally occur to one of ordinary skill in the art.

The present invention may be described in terms of functional block components and various processing steps. Such functional blocks may be realized by any number of hardware and/or software components configured to perform the specified functions. For example, the present invention may employ various integrated circuit components, e.g., memory elements, processing elements, logic elements, look-up tables, and the like, which may carry out a variety of functions under the control of one or more microprocessors or other control devices. Similarly, where the elements of the present invention are implemented using software programming or software elements the invention may be implemented with any programming or scripting language such as C, C++, Java, assembler, or the like, with the various algorithms being implemented with any combination of data structures, objects, processes, routines or other programming elements. Furthermore, the present invention could employ any number of conventional techniques for electronics configuration, signal processing and/or control, data processing and the like. The words “mechanism” and “element” are used broadly and are not limited to mechanical or physical embodiments, but can include software routines in conjunction with processors, etc.

The particular implementations shown and described herein are illustrative examples of the invention and are not intended to otherwise limit the scope of the invention in any way. For the sake of brevity, conventional electronics, control systems, software development and other functional aspects of the systems (and components of the individual operating components of the systems) may not be described in detail. Furthermore, the connecting lines, or connectors shown in the various figures presented are intended to represent exemplary functional relationships and/or physical or logical couplings between the various elements. It should be noted that many alternative or additional functional relationships, physical connections or logical connections may be present in a practical device. Moreover, no item or component is essential to the practice of the invention unless the element is specifically described as “essential” or “critical”.

The use of the terms “a” and “an” and “the” and similar referents in the context of describing the invention (especially in the context of the following claims) are to be construed to cover both the singular and the plural. Furthermore, recitation of ranges of values herein are merely intended to serve as a shorthand method of referring individually to each separate value falling within the range, unless otherwise indicated herein, and each separate value is incorporated into the specification as if it were individually recited herein. Finally, the steps of all methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed.

Numerous modifications and adaptations will be readily apparent to those skilled in this art without departing from the spirit and scope of the present invention.

What is claimed is:

1. A method for preparing a plurality of groupings of light-emitting diode (LED) lights, where each grouping comprises a plurality of LEDs that fall within a specified color range from respective target x, y color points, the method comprising:
receiving a source group of LEDs from a supplier, the source group having a specified color range;
measuring a color value for each LED in the source group with a color sensor;
storing the measured color value for each LED in the source group along with a unique LED identifier;
creating a first grouping of LEDs within the specified color range from a first target x, y color point by identifying a plurality of LEDs from the stored color values that fall within the specified color range;
creating a second grouping of LEDs within the specified color range from a second target x, y color point that is different from the first target x, y color point by identifying a plurality of LEDs from the stored color values that fall within the specified color range; and
applying a physical or virtual said unique identifier related a first LED falling within the first grouping of LEDs to the first LED or a housing holding the first LED; and
applying a physical or virtual said unique identifier related a second LED falling within the second grouping of LEDs to the second LED or a housing holding the second LED.

2. A method for preparing a plurality of groupings of light-emitting diode (LED) lights, where each grouping comprises a plurality of LEDs that fall within a specified color range from respective target x, y color points, the method comprising:
receiving a source group of LEDs from a supplier, the source group having a specified color range;
measuring a color value for each LED in the source group with a color sensor;
storing the measured color value for each LED in the source group along with a unique LED identifier;
creating a first grouping of LEDs within the specified color range from a first target x, y color point by identifying a plurality of LEDs from the stored color values that fall within the specified color range;
creating a second grouping of LEDs within the specified color range from a second target x, y color point that is different from the first target x, y color point by identifying a plurality of LEDs from the stored color values that fall within the specified color range; and
assembling a first lighting assembly utilizing the first grouping of LEDs; and
assembling a second lighting assembly utilizing the second grouping of LEDs.

3. The method of claim 2, further comprising:
applying a physical or virtual said unique identifier related a first LED falling within the first grouping of LEDs to the first LED or a housing holding the first LED; and
applying a physical or virtual said unique identifier related a second LED falling within the second grouping of LEDs to the second LED or a housing holding the second LED.

4. The method of claim 3, wherein the applying is applying a machine-readable label to the housings.

5. The method of claim 2, wherein the storing is done in a memory of the LED lights.

6. The method of claim 2, further comprising:
defining a second specified color range that is greater than the specified color range, and within which the first grouping of LEDs and the second grouping of LEDs must fall within.

7. The method of claim 2, wherein the first lighting assembly is a single unit with elements sharing a common panel, and the second lighting assembly is a single unit with elements sharing a common panel, the second lighting assembly being physically separate from the first lighting assembly.

8. The method of claim 7, wherein each of the first and second lighting assemblies comprises either two, three, or four LED lights.

9. The method of claim 2, wherein the color points are points on the CIE 1931 Chromaticity Diagram.

10. The method of claim 2, wherein the specified color range is less than at least one of: a) three standard deviations of color matching (SDCM); and b) 1.5 MacAdams Ellipse (ME) diameters.

11. The method of claim 2, further comprising:
providing a color filter for at least one of the first lighting assembly or the second lighting assembly.

12. The method of claim 11, wherein the measuring of a color value for each LED in the source group includes measuring with the color filter.

13. The method of claim 12, wherein the stored measured color value is the measured color value with the filter.

14. The method of claim 12, further comprising additionally storing the measured color value measured with the filter.

15. The method of claim 2, wherein the specified color range from the first target x, y color point and the specified color range from the second target x, y color point overlap, and a particular LED falls within an overlapping area, the particular LED being associated with the first grouping of LEDs and the second grouping of LEDs.

16. The method of claim 2, further comprising:
utilizing, during the measuring of the color value, an additional standardized illumination source.

17. A light-emitting diode (LED) system, comprising:
a first LED lighting panel; and
a second LED lighting panel;
wherein each of the first and second LED lighting panels comprise:
a plurality of LED lights, each having an LED and a unique identifier that is associated with a measured color value;
wherein the plurality of LED lights for the first LED lighting panel comprise a first grouping of LEDs within a specified color range from a first target x, y color point, and the plurality of LED lights for the second LED lighting panel comprise a second grouping of LEDs within a specified color range from a second target x, y color point that is different from a first target x, y color point.
